(19) United States
(12) Patent Application Publication
(10) Pub. No.: US 2025/0063882 A1
(43) Pub. Date: Feb. 20, 2025

(54) DETECTION DEVICE

(71) Applicant: Japan Display Inc., Tokyo (JP)

(72) Inventor: Gen KOIDE, Tokyo (JP)

(21) Appl. No.: 18/939,911

(22) Filed: Nov. 7, 2024

Related U.S. Application Data
(63) Continuation of application No. PCT/JP2023/017360, filed on May 9, 2023.

(30) Foreign Application Priority Data
May 17, 2022 (JP) 2022-081147

(51) Int. Cl. H10K 39/32; H10K 30/81; H10K 39/38

(52) U.S. Cl. CPC H10K 39/32; H10K 30/81; H10K 39/38

(57) ABSTRACT

According to an aspect, a detection device includes: a substrate; and a photodiode in which a lower electrode, a lower buffer layer, an active layer, an upper buffer layer, and an upper electrode are stacked on the substrate in the order as listed. In plan view, the lower electrode is provided so as to extend from an area overlapping an organic semiconductor layer including the lower buffer layer, the active layer, and the upper buffer layer to an area outside a side surface of the organic semiconductor layer.

### CROSS-REFERENCE TO RELATED APPLICATION

This application claims the benefit of priority from Japanese Patent Application No. 2022-081147 filed on May 17, 2022 and International Patent Application No. PCT/JP2023/017360 filed on May 9, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vein patterns are known (refer to, for example, Japanese Patent Application Laid-open Publication No. 2009-032005). Such optical sensors each include a plurality of photodiodes each including an organic semiconductor material as an active layer. As described in International Patent Application Publication No. WO/2020/188959, each of the photodiodes is disposed between a lower electrode and an upper electrode; and, for example, the lower electrode, an electron transport layer, the active layer, a hole transport layer, and the upper electrode are stacked in this order. The electron transport layer and the hole transport layer are also called buffer layers.

An organic semiconductor layer including an electron transport layer, an active layer, and a hole transport layer may be provided having a larger area than the lower electrode. Photocarriers generated in a portion of the organic semiconductor layer that does not overlap the lower electrode reach the lower electrode later than photocarriers generated in a portion of the organic semiconductor layer that overlaps the lower electrode. As a result, the photocarriers generated in the portion of the organic semiconductor layer that does not overlap the lower electrode may not be sufficiently read out, and the accuracy of detection may decrease. Otherwise, since the photocarriers generated in the portion of the organic semiconductor layer that does not overlap the lower electrode is read out, the readout period increases, and the detection speed may decrease.

For the foregoing reasons, there is a need for a detection device capable of improving accuracy of detection.

### SUMMARY

According to an aspect, a detection device includes: a substrate; and a photodiode in which a lower electrode, a lower buffer layer, an active layer, an upper buffer layer, and an upper electrode are stacked on the substrate in the order as listed. In plan view, the lower electrode is provided so as to extend from an area overlapping an organic semiconductor layer including the lower buffer layer, the active layer, and the upper buffer layer to an area outside a side surface of the organic semiconductor layer.

### BRIEF DESCRIPTION OF THE DRAWINGS

FIG. 1 is a plan view illustrating a detection device according to a first embodiment;

FIG. 2 is a circuit diagram illustrating the detection device according to the first embodiment;

FIG. 3 is a sectional view along III-III′ of FIG. 1;

FIG. 4 is a plan view schematically illustrating a coupling configuration between an upper electrode and a terminal;

FIG. 5 is a sectional view along V-V′ of FIG. 4;

FIG. 6 is a plan view illustrating a detection device according to a second embodiment;

FIG. 7 is a circuit diagram illustrating the detection device according to the second embodiment;

FIG. 8 is a plan view illustrating, in an enlarged manner, four photodiodes arranged at a corner of a detection area;

FIG. 9 is a sectional view along IX-IX′ of FIG. 8; and

FIG. 10 is a sectional view along X-X′ of FIG. 6.

### DETAILED DESCRIPTION

The following describes modes (embodiments) for carrying out the present invention in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

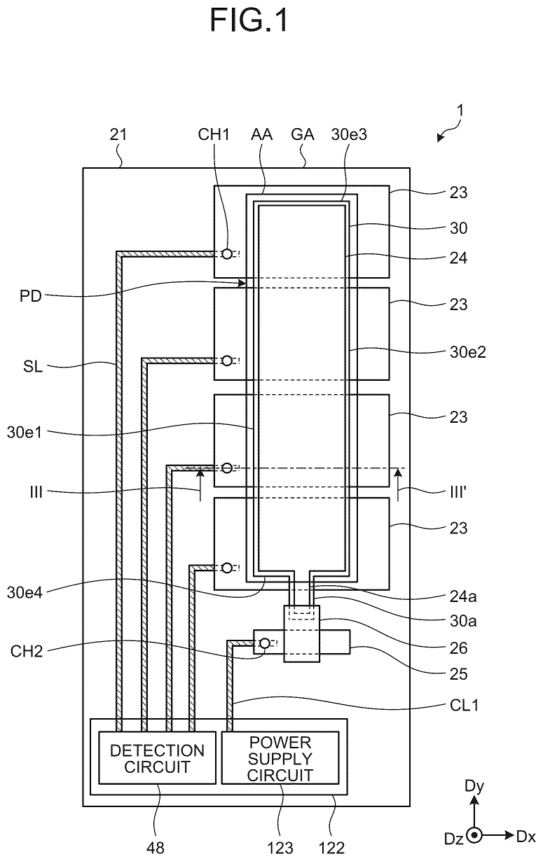

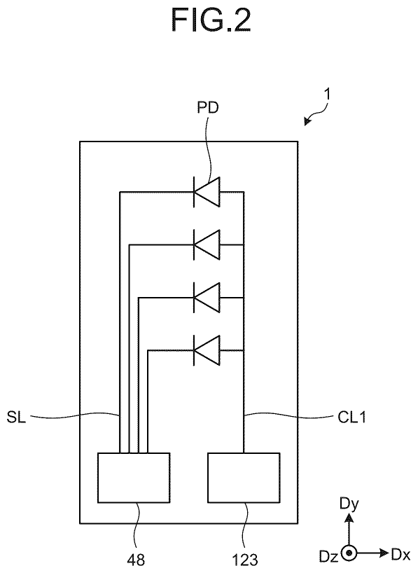

FIG. 1 is a plan view illustrating a detection device according to a first embodiment. FIG. 2 is a circuit diagram illustrating the detection device according to the first embodiment. As illustrated in FIGS. 1 and 2, a detection device 1 includes a substrate 21, a plurality of photodiodes PD, a plurality of signal lines SL, a power supply wiring line CL1, and a control circuit 122.

The substrate 21 has a detection area AA and a peripheral area GA. The detection area AA is an area provided with the photodiodes PD. The peripheral area GA is an area between the outer perimeter of the detection area AA and the ends of the substrate 21, and is an area not provided with the photodiodes PD. The signal lines SL and the control circuit 122 are provided in the peripheral area GA of the substrate 21.

In the following description, a first direction Dx is one direction in a plane parallel to the substrate 21. A second direction Dy is one direction in the plane parallel to the substrate 21, and is a direction orthogonal to the first direction Dx. The second direction Dy may non-orthogonally intersect the first direction Dx. A third direction Dz is a direction orthogonal to the first direction Dx and the second direction Dy. The third direction Dz is a direction normal to the substrate 21. The term “plan view” refers to a positional relation when viewed in a direction orthogonal to the substrate 21.

The detection device 1 includes the photodiodes PD as optical sensor elements. Each of the photodiodes PD outputs an electrical signal corresponding to light emitted thereto. More specifically, the photodiode PD is an organic photodiode (OPD) including an organic semiconductor. The photodiodes PD are arranged in the second direction Dy in the detection area AA.

As illustrated in FIG. 2, the cathode (lower electrode 23) of each of the photodiodes PD is coupled to a detection circuit 48 through a corresponding one of the signal lines SL. The anode (upper electrode 24) of the photodiodes PD is coupled to a power supply circuit 123 through the common power supply wiring line CL1.

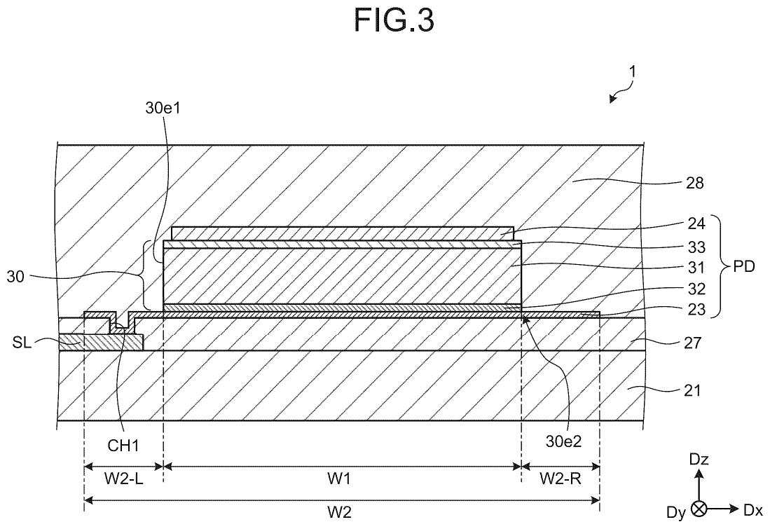

More specifically, as illustrated in FIG. 1, the photodiodes PD each include an organic semiconductor layer 30 (a lower buffer layer 32, an active layer 31, and an upper buffer layer 33 (refer to FIG. 3)), the lower electrode 23 disposed below the organic semiconductor layer 30, and the upper electrode 24 disposed on the organic semiconductor layer 30. A plurality of the lower electrodes 23 are provided, one for each of the photodiodes PD, and are arranged in the second direction Dy in the detection area AA. The lower electrodes 23 are arranged apart from one another in the second direction Dy.

The organic semiconductor layer 30 and the upper electrode 24 are provided so as to extend in the second direction Dy across the photodiodes PD and are provided continuously in the detection area AA. The organic semiconductor layer 30 has four side surfaces 30e1, 30e2, 30e3, and 30e4, and is formed in a substantially rectangular shape in plan view. The organic semiconductor layer 30 has the side surface 30e1 on one side in the first direction Dx, the side surface 30e2 on the other side in the first direction Dx, the side surface 30e3 on one side in the second direction Dy, and the side surface 30e4 on the other side in the second direction Dy. The side surface 30e2 is located on the opposite side to the side surface 30e1 in the first direction Dx. The side surface 30e4 is located on the opposite side to the side surface 30e3 in the second direction Dy. A multilayer configuration of the photodiode PD, the lower electrode 23, and the upper electrode 24 will be described later with reference to FIG. 3.

The signal lines SL are electrically coupled to the respective lower electrodes 23 of the photodiodes PD. Specifically, in the example illustrated in FIG. 1, the signal lines SL are each coupled to a corresponding one of the lower electrodes 23 through a contact hole CH1 formed in an insulating film 27 (illustrated in FIG. 3).

Each of the signal lines SL extends in the first direction Dx from a connection portion (contact hole CH1) to the lower electrode 23, bends to the second direction Dy, and extends in the second direction Dy along the arrangement direction of the photodiodes PD. Portions of the signal lines SL extending in the second direction Dy are arranged in the first direction Dx. The signal lines SL are coupled to the detection circuit 48 included in the control circuit 122. In other words, the detection circuit 48 is electrically coupled to the lower electrodes 23 of the photodiodes PD through the signal lines SL.

The upper electrode 24 is provided so as to extend in the second direction Dy across the detection area AA and the peripheral area GA. Coupling portions 24a and 30a are provided at outer edges on the other side (lower side in FIG. 1) in the second direction Dy of the upper electrode 24 and the organic semiconductor layer 30, respectively. The coupling portions 24a and 30a are provided so as to extend from the detection area AA toward the peripheral area GA, and are electrically coupled to a terminal 25 through a conductive layer 26. The terminal 25 is electrically coupled to the power supply wiring line CL1 through a contact hole CH2.

With such a configuration, the upper electrode 24 of the photodiodes PD is coupled to the power supply circuit 123 included in the control circuit 122 via the conductive layer 26, the terminal 25, and the power supply wiring line CL1. The power supply circuit 123 supplies a sensor reference voltage COM to the upper electrode 24 of the photodiodes PD.

The control circuit 122 (detection circuit 48 and power supply circuit 123) is disposed adjacent to the photodiodes PD in the second direction Dy in the peripheral area GA of the substrate 21. The control circuit 122 is a circuit that controls detection operations by supplying control signals to the photodiodes PD. Each of the photodiodes PD outputs, to the detection circuit 48, the electrical signal corresponding to the light emitted thereto as a detection signal Vdet. In the present embodiment, the detection signals Vdet of the photodiodes PD are sequentially output to the detection circuit 48 in a time-division manner. In other words, the signal lines SL are sequentially electrically coupled to the detection circuit 48 in a time-division manner. Thereby, the detection device 1 detects information on an object to be detected based on the detection signals Vdet from the photodiodes PD.

The control circuit 122 (detection circuit 48 and power supply circuit 123) is provided on the same substrate 21 as the photodiodes PD, but is not limited to this configuration. The control circuit 122 (detection circuit 48 and power supply circuit 123) may be provided on another control substrate coupled to the substrate 21, for example, through a flexible printed circuit board or the like. The detection circuit 48 and the power supply circuit 123 may each be formed as an individual circuit.

Although not illustrated in FIG. 1, the detection device 1 may include one or more light sources. For example, an inorganic light-emitting diode (LED) or an organic electroluminescent (EL) diode (organic light-emitting diode (OLED)) is used as the light source.

Light emitted from the light source is reflected by the object to be detected such as a finger and enters the photodiodes PD. As a result, the detection device 1 can detect a fingerprint by detecting a shape of asperities on the surface of the finger or the like. Alternatively, the light emitted from the light source may be reflected in the finger or the like, or transmitted through the finger or the like, and enter the photodiodes PD. As a result, the detection device 1 can detect information on a living body in the finger or the like. Examples of the information on the living body include, but are not limited to, pulse waves, pulsation, and a vascular image of the finger or a palm. That is, the detection device 1 may be configured as a fingerprint detection device to detect a fingerprint or a vein detection device to detect a vascular pattern of, for example, veins.

The following describes a multilayer configuration of the organic semiconductor layer 30, the lower electrode 23, and the upper electrode 24 of the photodiode PD. FIG. 3 is a sectional view along III-III′ of FIG. 1.

In the following description, a direction from the substrate 21 toward a sealing film 28 in a direction orthogonal to a surface of the substrate 21 is referred to as “upper side” or simply “above”. A direction from the sealing film 28 toward the substrate 21 is referred to as “lower side” or simply “below”.

As illustrated in FIG. 3, the substrate 21 is an insulating substrate and is made using, for example, glass or a resin material. The substrate 21 is not limited to having a flat plate shape and may have a curved surface. In this case, the substrate 21 may be made of a film-like resin.

The signal line SL is provided on the substrate 21. The signal line SL is formed, for example, of metal wiring, and is formed of a material having better conductivity than the lower electrode 23 of the photodiode PD. A portion of the signal line SL (the right end side of the signal line SL in FIG. 3) is provided in a layer between the substrate 21 and the lower electrode 23 of the photodiode PD in the third direction Dz. The insulating film 27 is provided on the substrate 21 so as to cover the signal line SL. The insulating film 27 may be an inorganic insulating film or an organic insulating film. The insulating film 27 may be a single layer or a multilayered film.

The photodiode PD is provided on the insulating film 27. More specifically, the photodiode PD includes the lower electrode 23, the lower buffer layer 32, the active layer 31, the upper buffer layer 33, and the upper electrode 24. In the photodiode PD, the lower electrode 23, the lower buffer layer 32 (electron transport layer), the active layer 31, the upper buffer layer 33 (hole transport layer), and the upper electrode 24 are stacked in this order in the direction orthogonal to the substrate 21.

The lower electrode 23 is provided on the insulating film 27 and is electrically coupled to the signal line SL through the contact hole CH1 provided in the insulating film 27. The lower electrode 23 is a cathode electrode of the photodiode PD and is formed, for example, of a light-transmitting conductive material such as indium tin oxide (ITO). The detection device 1 of the present embodiment is formed as a bottom-surface light receiving optical sensor in which the light from the object to be detected passes through the substrate 21 and enters the photodiode PD.

The active layer 31 changes in characteristics (for example, voltage-current characteristics and resistance value) according to light emitted thereto. An organic material is used as a material of the active layer 31. Specifically, the active layer 31 has a bulk heterostructure containing a mixture of a p-type organic semiconductor and an n-type fullerene derivative ((6,6]-phenyl-C61-butyric acid methyl ester (PCBM)) that is an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly (3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is an electron transport layer and the upper buffer layer 33 is a hole transport layer. The lower buffer layer 32 and the upper buffer layer 33 are provided to facilitate holes and electrons generated in the active layer 31 to reach the lower electrode 23 or the upper electrode 24. The lower buffer layer 32 (electron transport layer) is in direct contact with the top of the lower electrode 23. The active layer 31 is in direct contact with the top of the lower buffer layer 32. Polyethylenimine ethoxylated (PEIE) is used as a material of the electron transport layer.

The upper buffer layer 33 (hole transport layer) is in direct contact with the top of the active layer 31, and the upper electrode 24 is in direct contact with the top of the upper buffer layer 33. The material of the hole transport layer is a metal oxide layer. Tungsten oxide (WO₃), molybdenum oxide, or the like is used as the metal oxide layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, and may be formed as a multilayered film that includes an electron block layer and a hole block layer.

The upper electrode 24 is provided on the upper buffer layer 33. The upper electrode 24 is an anode electrode of the photodiodes PD and is continuously formed over the entire detection area AA. In other words, the upper electrode 24 is continuously provided on the photodiodes PD. The upper electrode 24 faces the lower electrodes 23 with the lower buffer layer 32, the active layer 31, and the upper buffer layer 33 interposed therebetween. The upper electrode 24 is formed, for example, of a light-transmitting conductive material such as ITO or indium zinc oxide (IZO).

The sealing film 28 is provided on the upper electrode 24. An inorganic film, such as a silicon nitride film or an aluminum oxide film, or a resin film, such as an acrylic film, is used as the sealing film 28. The sealing film 28 is not limited to a single layer, and may be a multilayered film having two or more layers obtained by combining the inorganic film with the resin film mentioned above. The sealing film 28 well seals the photodiodes PD, and thus can reduce moisture entering the photodiodes PD from the upper surface side thereof.

In the present embodiment, the lower electrode 23 is provided so as to extend from an area overlapping the organic semiconductor layer 30 including the lower buffer layer 32, the active layer 31, and the upper buffer layer 33 to areas outside the side surfaces 30e1 and 30e2 of the organic semiconductor layer 30. More specifically, the lower electrode 23 is provided so as to extend to an area outside the side surface 30e1 on the one side in the first direction Dx of the organic semiconductor layer 30, and is provided so as to extend to an area outside the side surface 30e2 on the other side in the first direction Dx of the organic semiconductor layer 30. That is, a width W2 in the first direction Dx of the lower electrode 23 is larger than a width W1 in the first direction Dx of the organic semiconductor layer 30. In other words, the lower electrode 23 includes a portion overlapping the organic semiconductor layer 30 and a portion not overlapping the organic semiconductor layer 30, in the first direction Dx. The organic semiconductor layer 30 is disposed so as to overlap the lower electrode 23 from the side surface 30e1 on the one side in the first direction Dx to the side surface 30e2 on the other side in the first direction Dx.

With such a configuration, the organic semiconductor layer 30 does not have a portion that does not overlap the lower electrode 23 at least in the first direction Dx. Therefore, the photocarriers generated in the organic semiconductor layer 30 more quickly reach the lower electrode 23 than in a configuration in which the organic semiconductor layer 30 extends outside the outer edge of the lower electrode 23 so as to cover the lower electrode 23. Therefore, the detection device 1 can reduce delays in optical response and improve accuracy of detection.

A width W2-L of a portion of the lower electrode 23 extending outside the side surface 30e1 of the organic semiconductor layer 30 is equal to a width W2-R of a portion extending outside the side surface 30e2 of the organic semiconductor layer 30 on the opposite side in the first direction Dx. However, the present disclosure is not limited to this configuration. The width W2-L may be different from the width W2-R. The length of each of the widths W2-L and W2-R is determined, for example, to be larger than the amount of positional deviation in coating and patterning processes when forming the organic semiconductor layer 30.

FIG. 3 illustrates the configuration in which the lower electrode 23 extends to the areas outside the side surfaces 30e1 and 30e2 of the organic semiconductor layer 30 in the first direction Dx, but the configuration is not limited to this illustration. As illustrated in FIG. 1, the lower electrode 23 disposed outermost on one side in the second direction Dy (upper side in FIG. 1) (lower electrode 23 farthest from the terminal 25) is provided so as to extend to areas outside the side surfaces 30e1 and 30e2 in the first direction Dx of the organic semiconductor layer 30, and is provided to an area outside the side surface 30e3 on the one side in the second direction Dy.

The lower electrode 23 located outermost on the other side in the second direction Dy (lower side in FIG. 1) (lower electrode 23 closest to the terminal 25) is provided so as to extend to areas outside the side surfaces 30e1 and 30e2 in the first direction Dx of the organic semiconductor layer 30, and is provided to an area outside the side surface 30e4 on the other side in the second direction Dy.

With such a configuration, the side surface 30e3 on the one side in the second direction Dy and the side surface 30e4 on the other side in the second direction Dy of the organic semiconductor layer 30 are each located inside the outermost periphery of the lower electrodes 23. As a result, the photocarriers generated in the organic semiconductor layer 30 quickly reach the lower electrodes 23 in the photodiodes PD located outermost on the one side and the other side in the second direction Dy, and the delays in optical response can be reduced.

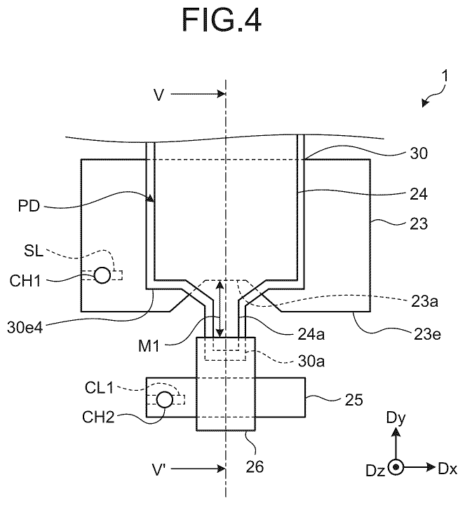

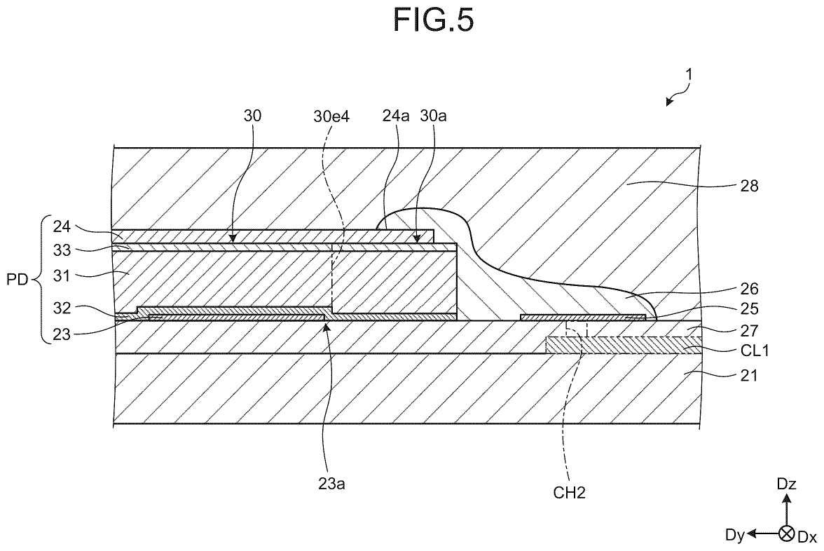

The following describes, in detail, a coupling configuration between the upper electrode 24 of the photodiodes PD and both the terminal 25 and the power supply wiring line CL1. FIG. 4 is a plan view schematically illustrating the coupling configuration between the upper electrode and the terminal. FIG. 5 is a sectional view along V-V′ of FIG. 4.

As illustrated in FIGS. 4 and 5, the lower electrode 23 of the photodiode PD among the photodiodes PD that corresponds to a portion where the upper electrode 24 is electrically coupled to the power supply wiring line CL1 has a notch 23a. Among the photodiodes PD, the photodiode PD that corresponds to the portion where the upper electrode 24 is electrically coupled to the power supply wiring line CL1 is located outermost on the other side in the second direction Dy (photodiode PD closest to the terminal 25).

The notch 23a of the lower electrode 23 is formed to be recessed in a trapezoidal shape from a central portion of an outer edge 23e of the lower electrode 23 toward the one side in the second direction Dy. The coupling portion 30a of the organic semiconductor layer 30 is disposed so as to overlap the notch 23a of the lower electrode 23 and projects in the second direction Dy from the side surface 30e4 of the organic semiconductor layer 30. A widened portion in which the width in the first direction Dx of the coupling portion 30a gradually increases is provided at a coupling position between the side surface 30e4 of the organic semiconductor layer 30 and the coupling portion 30a. The coupling portion 24a coupled to the upper electrode 24 is provided so as to overlap the coupling portion 30a of the organic semiconductor layer 30.

As illustrated in FIG. 5, the conductive layer 26 is provided so as to cover the upper surface of the coupling portion 24a of the upper electrode 24, and so as to cover a side surface of the coupling portion 24a of the upper electrode 24 and a side surface of the coupling portion 30a of the organic semiconductor layer 30. The conductive layer 26 extends in the second direction Dy from the side surface of the coupling portion 30a and is provided so as to overlap the terminal 25. The coupling portion 30a of the organic semiconductor layer 30 and the coupling portion 24a of the upper electrode 24 are formed so as to be continuously integrated with the organic semiconductor layer 30 and the upper electrode 24, and have the same multilayer structure as the organic semiconductor layer 30 and the upper electrode 24.

As described above, the terminal 25 is electrically coupled to the power supply wiring line CL1 through the contact hole CH2 provided in the insulating film 27. With such a configuration, the upper electrode 24 of the photodiodes PD is coupled to the power supply wiring line CL1 via the conductive layer 26 and the terminal 25.

In the present embodiment, the lower electrode 23 is provided with the notch 23a. Therefore, even if the conductive layer 26 is disposed close to the outer edge 23e of the lower electrode 23, a distance M1 in the second direction Dy between the notch 23a of the lower electrode 23 and the conductive layer 26 can be ensured. Thereby, the detection device 1 can ensure insulation between the lower electrode 23 and the conductive layer 26 and can achieve a narrower frame.

The coupling configuration between the upper electrode 24 and both the terminal 25 and the power supply wiring line CL1 illustrated in FIGS. 4 and 5 is merely exemplary and can be changed as appropriate. For example, the notch 23a of the lower electrode 23 can be omitted depending on the characteristics.

Alternatively, among the photodiodes PD, the photodiode PD that corresponds to the portion where the upper electrode 24 is electrically coupled to the power supply wiring line CL1 (photodiode PD located outermost on the other side in the second direction Dy in FIG. 1) may be a dummy photodiode. The dummy photodiode has the same multilayer structure as the photodiode PD, but is configured so as not to virtually serve as a photodiode. For example, a configuration may be employed in which the signal line SL is not coupled to the lower electrode 23 of the dummy photodiode, and the detection signal from the dummy photodiode is not output to the detection circuit 48. Alternatively, the detection circuit 48 may be configured not to use the detection signal received from the dummy photodiode to detect the information on the living body.

In the first embodiment described above, the configuration in which the detection device 1 includes four photodiodes PD has been described. The detection device 1 is not limited to this configuration and may include five or more photodiodes PD. Alternatively, the detection device 1 is not limited to a configuration including a plurality of the photodiodes PD and may include at least one photodiode PD.

In the first embodiment described above, the example has been described in which the photodiodes PD are arranged in the second direction Dy in the detection area AA. However, the present disclosure is not limited to this example. The photodiodes PD may be arranged in the first direction Dx in the detection area AA or may be arranged in the first direction Dx and the second direction Dy in the detection area AA to form a matrix having a row-column configuration.

### Second Embodiment

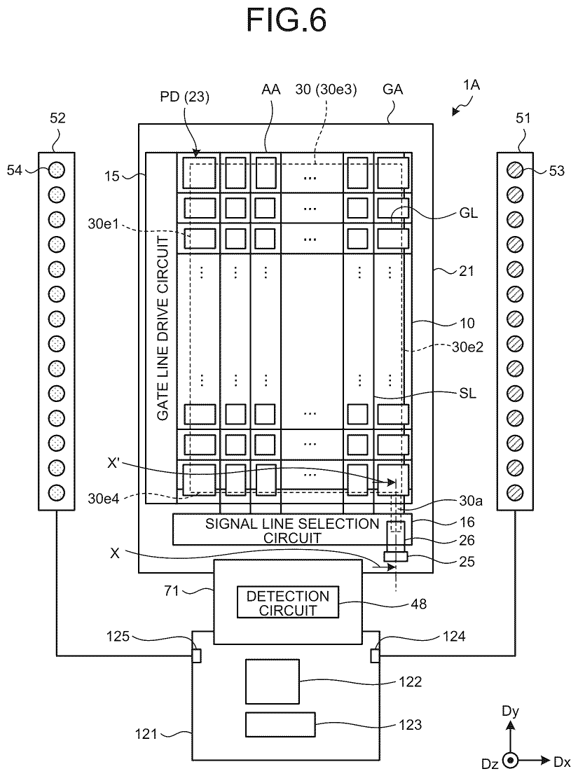

FIG. 6 is a plan view illustrating a detection device according to a second embodiment. In the following description, the same components as those described in the embodiment above are denoted by the same reference numerals, and the description thereof will not be repeated.

As illustrated in FIG. 6, a detection device 1A according to the second embodiment further includes a sensor 10 including the photodiodes PD, a plurality of gate lines GL, the signal lines SL, a gate line drive circuit 15, a signal line selection circuit 16, a first light source base member 51, a second light source base member 52, and light sources 53 and 54. The first light source base member 51 is provided with a plurality of the first light sources 53. The second light source base member 52 is provided with a plurality of the first light sources 54.

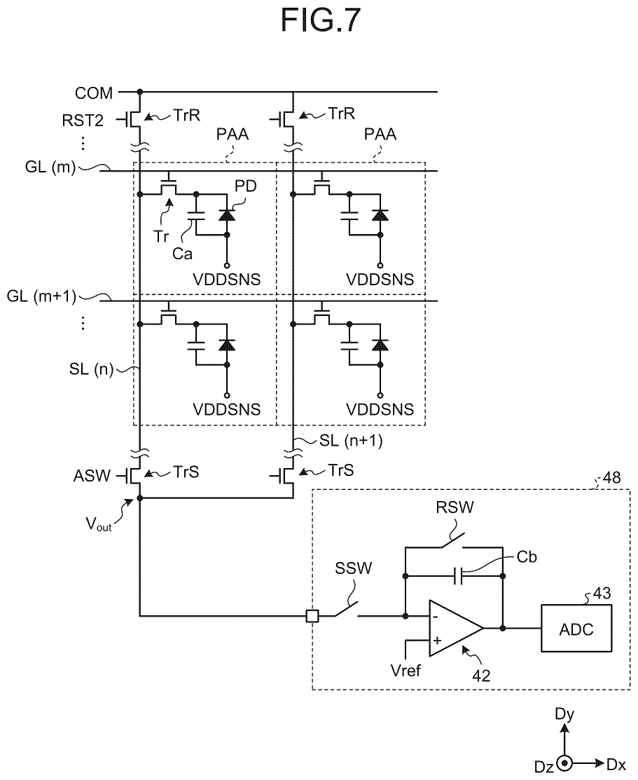

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 supplies control signals to the gate line drive circuit 15 and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals such as a sensor power supply signal (sensor power supply voltage) VDDSNS (refer to FIG. 7) to the sensor 10, the gate line drive circuit 15, and the signal line selection circuit 16. The power supply circuit 123 supplies a power supply voltage to the light sources 53 and 54.

The light sources 53 are provided on the first light source base member 51 and are arranged along the second direction Dy. The light sources 54 are provided on the second light source base member 52 and are arranged along the second direction Dy. The first light source base member 51 and the second light source base member 52 are electrically coupled to the control circuit 122 and the power supply circuit 123 through terminals 124 and 125, respectively, provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other. The detection device 1 is provided with a plurality of types of the light sources 53 and 54 as light sources. However, the light sources are not limited thereto and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

As illustrated in FIG. 6, in the detection device 1A according to the second embodiment, the photodiodes PD are arranged in a matrix having a row-column configuration in the detection area AA of the substrate 21. The lower electrodes 23 are provided corresponding to the photodiodes PD and arranged in a matrix having a row-column configuration in the detection area AA. In other words, the photodiodes PD (lower electrodes 23) are arranged in the first direction Dx and the second direction Dy.

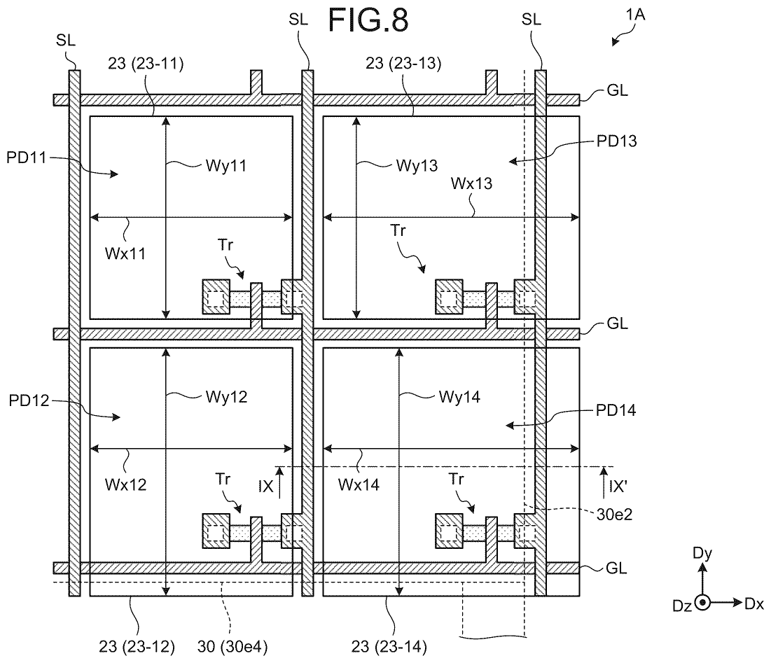

The organic semiconductor layer 30 and the upper electrode 24 are provided across the photodiodes PD and are provided continuously in the detection area AA. Although FIG. 6 does not illustrate the upper electrode 24, the upper electrode 24 is formed to have substantially the same shape as the organic semiconductor layer 30. In the detection device 1A of the present embodiment, the lower electrodes 23 of the photodiodes PD arranged at the outermost periphery extend to an area outside the side surfaces 30e1, 30e2, 30e3, and 30e4 of the organic semiconductor layer 30 in plan view. The configuration of the lower electrodes 23 at the outermost periphery will be described in detail with reference to FIG. 8.

The gate line drive circuit 15 and the signal line selection circuit 16 are provided in the peripheral area GA. The gate lines GL extend in the first direction Dx and are coupled to the gate line drive circuit 15. The signal lines SL extend in the second direction Dy and are coupled to the signal line selection circuit 16. Each of the photodiodes PD performs detection in response to a gate drive signal supplied from the gate line drive circuit 15. Each of the photodiodes PD outputs the electrical signal corresponding to the light emitted thereto as the detection signal Vdet to the signal line selection circuit 16. Thereby, the detection device 1A detects the information on the object to be detected based on the detection signals Vdet from the photodiodes PD.

More specifically, the gate line drive circuit 15 drives the gate lines GL row by row. That is, the gate line drive circuit 15 sequentially or simultaneously selects the gate lines GL and supplies the gate drive signal to the selected gate lines GL. As a result, drive transistors Tr (refer to FIG. 14) coupled to the gate lines GL are turned on (conductive state), and the lower electrodes 23 of the photodiodes PD coupled to the gate lines GL are electrically coupled to the signal lines SL via the drive transistors Tr.

The signal line selection circuit 16 is a switch circuit that sequentially or simultaneously selects the signal lines SL. The signal line selection circuit 16 is a multiplexer, for example. The signal line selection circuit 16 sequentially reads the signal lines SL. That is, the signal line selection circuit 16 couples the selected signal lines SL to the detection circuit 48 based on selection signals supplied from the control circuit 122 (refer to FIG. 1).

FIG. 7 is a circuit diagram illustrating the detection device according to the second embodiment. FIG. 7 also illustrates a circuit configuration of the detection circuit 48. As illustrated in FIG. 7, a partial detection area PAA includes the photodiode PD, a capacitive element Ca, and the drive transistor Tr. The capacitive element Ca is capacitance (sensor capacitance) generated in the photodiode PD and is equivalently coupled in parallel to the photodiode PD.

FIG. 7 illustrates two gate lines GL(m) and GL(m+1) arranged in the second direction Dy among the gate lines GL. FIG. 7 also illustrates two signal lines SL(n) and SL(n+1) arranged in the first direction Dx among the signal lines SL. The partial detection area PAA is an area surrounded by the gate lines GL and the signal lines SL.

The drive transistor Tr is provided for each of the photodiodes PD. The drive transistor Tr is configured as a thin-film transistor and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The other ones of the sources and the drains of the drive transistors Tr are each coupled to the cathode of the photodiode PD and the capacitive element Ca.

The anode of the photodiode PD is supplied with the sensor power supply signal VDDSNS from the power supply circuit 123 (refer to FIG. 6). The signal line SL and the capacitive element Ca are supplied with the sensor reference voltage COM serving as an initial potential of the signal line SL and the capacitive element Ca, from the power supply circuit 123 via a reset transistor TrR.

When the partial detection area PAA is irradiated with light in an exposure period, a current corresponding to the amount of the light flows through the photodiode PD. As a result, an electric charge is stored in the capacitive element Ca. After the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. The detection device 1A can thereby detect a signal corresponding to the amount of the light received by the photodiode PD in each of the partial detection areas PAA.

During the readout period, a switch SSW is turned on to couple the detection circuit 48 to the signal lines SL. A detection signal amplifying circuit 42 of the detection circuit 48 converts a current supplied from the signal line SL into a voltage corresponding to the value of the current, and amplifies the result. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates the difference between the detection signal Vdet when light is emitted and the detection signal Vdet when light is not emitted as a sensor output voltage Vo. The detection signal amplifying circuit 42 includes a capacitive element Cb and a reset switch RSW. During a reset period, the reset switch RSW is turned on to reset the electric charge of the capacitive element Cb.

FIG. 8 is a plan view illustrating, in an enlarged manner, four of the photodiodes arranged at a corner of the detection area. FIG. 8 illustrates, in an enlarged manner, four photodiodes PD11, PD12, PD13, and PD14 arranged at the corner among the photodiodes PD in the detection area AA.

The photodiode PD11 is disposed on a central side of the detection area AA, that is, more away from sides of the detection area AA than the photodiodes PD12, PD13, and PD14. A lower electrode 23-11 of the photodiode PD11 is provided in an area surrounded by two of the gate lines GL and two of the signal lines SL. The photodiodes PD12, PD13, and PD14 are arranged at outermost periphery of the detection area AA. The area of lower electrodes 23-12, 23-13, and 23-14 of the photodiodes PD12, PD13, and PD14 arranged at the outermost periphery are larger than the area of the lower electrode 23-11 of the photodiode PD11 disposed inside.

More specifically, the photodiode PD12 is provided adjacent to the photodiode PD11 in the second direction Dy, and along a side of the detection area AA extending in the first direction Dx. The lower electrode 23-12 of the photodiode PD12 disposed at the outermost periphery in the second direction Dy is provided so as to extend in the second direction Dy to an area outside the side surface 30e4 of the organic semiconductor layer 30 in plan view. A width Wx12 in the first direction Dx of the lower electrode 23-12 of the photodiode PD12 is equal to a width Wx11 in the first direction Dx of the lower electrode 23-11 of the photodiode PD11. A width Wy12 in the second direction Dy of the lower electrode 23-12 of the photodiode PD12 is larger than a width Wy11 in the second direction Dy of the lower electrode 23-11 of the photodiode PD11.

The photodiode PD13 is provided adjacent to the photodiode PD11 in the first direction Dx, and along a side of the detection area AA extending in the second direction Dy. The lower electrode 23-13 of the photodiode PD13 disposed at the outermost periphery in the first direction Dx is provided so as to extend in the first direction Dx to an area outside the side surface 30e2 of the organic semiconductor layer 30 in plan view. A width Wx13 in the first direction Dx of the lower electrode 23-13 of the photodiode PD13 is larger than the width Wx11 in the first direction Dx of the lower electrode 23-11 of the photodiode PD11. A width Wy13 in the second direction Dy of the lower electrode 23-13 of the photodiode PD13 is equal to the width Wy11 in the second direction Dy of the lower electrode 23-11 of the photodiode PD11.

The photodiode PD14 is diagonally adjacent to the photodiode PD11 and is provided at a corner of the detection area AA. The lower electrode 23-14 of the photodiode PD14 disposed at the corner of the outermost periphery of the detection area AA extends in the first direction Dx and the second direction Dy to an area outside the side surface 30e2 and the side surface 30e4 of the organic semiconductor layer 30 in plan view. A width Wx14 in the first direction Dx of the lower electrode 23-14 of the photodiode PD14 is larger than the width Wx11 in the first direction Dx of the lower electrode 23-11 of the photodiode PD11. A width Wy14 in the second direction Dy of the lower electrode 23-14 of the photodiode PD14 is larger than the width Wy11 in the second direction Dy of the lower electrode 23-11 of the photodiode PD11.

While FIG. 8 illustrates the four photodiodes PD11, PD12, PD13, and PD14, the description with reference to FIG. 8 is also applicable to other photodiodes PD arranged in the central portion of the detection area AA, and other photodiodes PD arranged at the outermost periphery of the detection area AA.

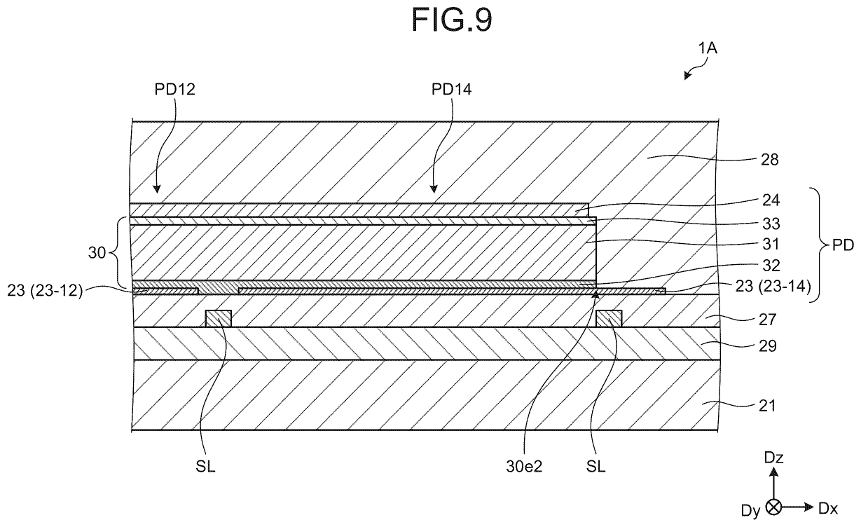

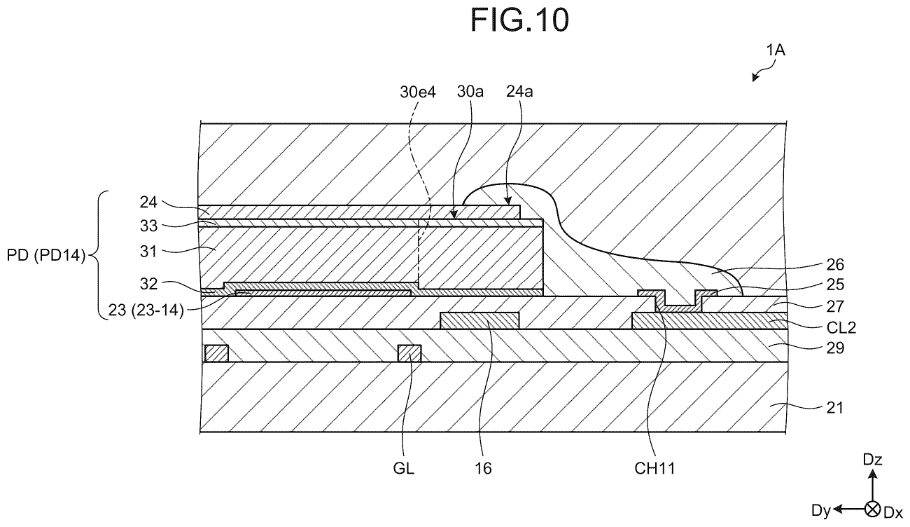

FIG. 9 is a sectional view along IX-IX′ of FIG. 8. As illustrated in FIG. 9, the organic semiconductor layer 30 is provided across the photodiodes PD (FIG. 9 illustrates the photodiodes PD12 and PD14). The lower electrode 23-12 of the photodiode PD12 and the lower electrode 23-14 of the photodiode PD14 are arranged apart from each other with a space provided in a position overlapping the signal line SL interposed therebetween. An insulating film 29 is provided on the substrate 21 so as to cover the gate lines GL (refer to FIG. 10). The insulating film 27 is provided on the insulating film 29 so as to cover the signal lines SL. The insulating films 27 and 29 may be an inorganic insulating film or an organic insulating film. The insulating films 27 and 29 may be a single layer or a multilayered film.

The lower electrode 23-14 of the photodiode PD14 is provided extending from an area overlapping the organic semiconductor layer 30 to an area outside the side surface 30e2 of the organic semiconductor layer 30. A portion of the lower electrode 23-14 extending outside the side surface 30e2 is provided so as to overlap the signal line SL at the outermost periphery.

FIG. 10 is a sectional view along X-X′ of FIG. 6. FIG. 10 is a sectional view illustrating a coupling configuration between the upper electrode 24 and both the terminal 25 and power supply wiring CL2 in the detection device 1A. As illustrated in FIG. 10, the coupling portion 24a of the upper electrode 24 and the coupling portion 30a of the organic semiconductor layer 30 are provided in a position corresponding to the photodiode PD14 and extend in the second direction Dy from the side surface 30e4 of the organic semiconductor layer 30. The coupling portion 30a of the organic semiconductor layer 30 is provided so as to extend on the upper side of the signal line selection circuit 16 and extends to a position closer to the terminal 25 than the signal line selection circuit 16.

The conductive layer 26 is provided so as to cover the upper surface of the coupling portion 24a of the upper electrode 24, and so as to cover the side surface of the coupling portion 24a of the upper electrode 24 and the side surface of the coupling portion 30a of the organic semiconductor layer 30. The conductive layer 26 is provided so as to extend in the second direction Dy from the side surface of the coupling portion 30a, and so as to overlap the terminal 25. The terminal 25 is electrically coupled to the power supply wiring CL2 through a contact hole CH11 provided in the insulating film 27.

With such a configuration, the upper electrodes 24 of the photodiodes PD are electrically coupled to the power supply wiring CL2 via the conductive layer 26 and the terminal 25. The sensor power supply signal VDDSNS (refer to FIG. 7) is supplied, via the power supply wiring CL2, to the upper electrodes 24 that are the anodes of the photodiodes PD.

In also the second embodiment, the notch 23a (refer to FIG. 4) may be provided at the lower electrode 23-14 of the photodiode PD14 provided with the coupling portion 30a of the organic semiconductor layer 30.

In the second embodiment, with the configuration described above, the area of a non-overlapping portion of the organic semiconductor layer 30 of the photodiode PD disposed at the outermost periphery can be made smaller compared with a configuration in which the organic semiconductor layer 30 is provided so as to cover the lower electrode 23 and extend outward beyond the outermost periphery of the lower electrode 23. The non-overlapping portion of the organic semiconductor layer 30 is a portion that does not overlap the lower electrode 23. As a result, the photocarriers generated at the outer edge of the organic semiconductor layer 30 quickly reach the lower electrode 23. Therefore, the detection device 1A can reduce the delays in optical response and improve the accuracy of detection.

In the first and the second embodiments described above, the lower electrode 23 is the cathode electrode of the photodiode PD, and the upper electrode 24 is the anode electrode of the photodiode PD. However, the present disclosure is not limited thereto, and the lower electrode 23 may be the anode electrode of the photodiode PD, and the upper electrode 24 may be the cathode electrode of the photodiode PD. In that case, the photodiode PD is configured such that the lower buffer layer 32 includes the hole transport layer, and the upper buffer layer 33 includes the electron transport layer.

In the first and the second embodiments described above, the lower electrode 23 has a quadrilateral outer shape, but the outer shape is not limited to this. The lower electrode 23 may have other shapes, such as a polygonal shape and a circular shape.

While the preferred embodiments have been described above, the present invention is not limited to these embodiments. The content disclosed in the embodiments is merely an example and can be variously modified within the scope not departing from the gist of the present invention. Any modifications appropriately made within the scope not departing from the gist of the present invention also naturally belong to the technical scope of the present invention. At least one of various omissions, substitutions, and changes of the components can be made without departing from the gist of the embodiments and modifications described above.

What is claimed is:

1. A detection device comprising:
a substrate; and
a photodiode in which a lower electrode, a lower buffer layer, an active layer, an upper buffer layer, and an upper electrode are stacked on the substrate in the order as listed, wherein
in plan view, the lower electrode is provided so as to extend from an area overlapping an organic semiconductor layer comprising the lower buffer layer, the active layer, and the upper buffer layer to an area outside a side surface of the organic semiconductor layer.

2. The detection device according to claim 1, comprising a plurality of the photodiodes, wherein
a plurality of the lower electrodes are arranged corresponding to the photodiodes and are provided so as to extend to at least an area outside a side surface in a first direction of the organic semiconductor layer,
the photodiodes are arranged in a second direction intersecting the first direction, and
the upper electrode is provided so as to extend in the second direction across the photodiodes.

3. The detection device according to claim 2, wherein
the lower electrodes are arranged in the second direction, and
the lower electrode disposed outermost in the second direction is provided so as to extend to an area outside the side surface in the first direction of the organic semiconductor layer and is provided so as to extend to an area outside a side surface in the second direction of the organic semiconductor layer.

4. The detection device according to claim 1, comprising:
a signal line electrically coupled to the lower electrode of the photodiode;
a detection circuit electrically coupled to the photodiode via the signal line; and
a power supply wiring line electrically coupled to the upper electrode via a conductive layer, wherein
the upper electrode is configured to be supplied with a predetermined potential via the conductive layer and the power supply wiring line.

5. The detection device according to claim 1, comprising a plurality of the photodiodes arranged in a matrix having a row-column configuration in a first direction and a second direction intersecting the first direction, wherein
a plurality of the lower electrodes are arranged corresponding to the photodiodes,
the upper electrode is provided across the photodiodes, and
the lower electrode of the photodiode disposed at an outermost periphery is provided so as to extend to an area outside a side surface of the organic semiconductor layer in plan view.

6. The detection device according to claim 5, wherein an area of the lower electrode of the photodiode disposed at the outermost periphery is larger than an area of the lower electrode of the photodiode disposed inside.

7. The detection device according to claim 5, further comprising:
a plurality of gate lines coupled to a gate line drive circuit;
a plurality of signal lines coupled to a signal line selection circuit; and
a plurality of transistors provided corresponding to the photodiodes, wherein
each of the gate lines is coupled to the transistors arranged in the first direction,
each of the signal lines is coupled to the transistors arranged in the second direction,
the gate line drive circuit is configured to drive the gate lines row by row, and
the signal line selection circuit is configured to sequentially read the signal lines.

8. The detection device according to claim 2, wherein the photodiode among the photodiodes that corresponds to a portion where the upper electrode is electrically coupled to a power supply wiring line is a dummy photodiode.

9. The detection device according to claim 2, wherein the lower electrode of the photodiode among the photodiodes that corresponds to a portion where the upper electrode is electrically coupled to a power supply wiring line has a notch.

10. The detection device according to claim 1, wherein
the lower buffer layer comprises one of a hole transport layer and an electron transport layer, and
the upper buffer layer comprises the other of the hole transport layer and the electron transport layer.
